(19) United States
(12) Patent Application Publication
(10) Pub. No.: US 2007/0077354 A1
(43) Pub. Date: Apr. 5, 2007

(54) Thermal conditioning plate with gas gap leak

(75) Inventors: Paul A. O'Brien, San Jose, CA (US); Rushford A. Ogden, Daly City, CA (US); Yacov Elgar, Sunnyvale, CA (US); William A. Eckes, Castro Valley, CA (US); Patrick Duane, Castro Valley, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/241,795

(22) Filed: Sep. 30, 2005

(51) Int. Cl. C23C 16/00; C23C 14/00; B05C 11/00

(52) U.S. Cl. 427/248.1; 118/728; 118/50; 118/666

(57) ABSTRACT

Methods and apparatus enable thermal conditioning of a substrate in a vacuum chamber that is evacuated to a high vacuum pressure. The substrate rests on a thermally controlled support that defines a cavity area between an underside of the substrate and a recessed section of the support. A fence of the support bounds the recessed section and limits flow of a gas injected into the cavity area into an interior region of the vacuum chamber where the support and substrate are disposed. Accordingly, a pressure differential exists between the cavity area and the interior region of the vacuum chamber. This relatively higher pressure in the cavity area enables heat transfer between the support and substrate via the gas in the cavity area in order to adjust the temperature of the substrate.

### BACKGROUND OF THE INVENTION

1. Field of the Invention

Embodiments of the invention generally relate to apparatus and methods for thermally conditioning a substrate in a vacuum environment.

2. Description of the Related Art

Substrates in semiconductor processes typically sit on a stage in a high vacuum chamber during various processes. These processes often require temperature stabilization of the substrate to ensure quality of the process performed to the substrate inside the chamber. For example, successful completion of the process can require removing heat introduced into the substrate due to the process.

Direct contact with the substrate is generally avoided, which prevents conduction as a path for heat removal. Additionally, lack of any gas in the vacuum chamber further increases difficulty in removing heat from the substrate by preventing convection or gas conduction cooling. Consequently, prior approaches to adjusting the temperature of the substrate fail to permit varying the temperature of the substrate without significant contact with the substrate or raising vacuum pressure within the high pressure vacuum chamber beyond acceptable levels for the processes.

For example, prior approaches to stabilizing the temperature of the substrate include altering the temperature of the substrate at atmospheric pressure or in an intermediate low pressure environment prior to evacuation of the high pressure vacuum chamber to a desired high vacuum. Transitioning to the high vacuum environment can require handling of the substrate and exposes the substrate to gas expansion cooling, thereby effecting the temperature of the substrate. In addition, holding pressure at an intermediate level increases costs by adding to complexity and overall time of the process while still not enabling the substrate temperature to be changed as the substrate is being processed in the high vacuum environment.

Therefore, there exists a need for improved apparatus and methods for thermally conditioning a substrate in a vacuum environment.

### SUMMARY OF THE INVENTION

The invention generally relates to controlling the temperature of a substrate in a vacuum chamber. Thermally conditioning the substrate in the vacuum chamber can occur while the substrate is disposed in the chamber that is evacuated to a high vacuum environment. Further, processes performed to the substrate can be performed in the high vacuum environment during adjusting of the temperature of the substrate.

According to one embodiment, a method of adjusting a temperature of a substrate includes providing the substrate disposed on a support within a vacuum chamber, evacuating an interior region of the vacuum, injecting a gas below the substrate within a cavity defined by the support and a bottom surface of the substrate while maintaining a pressure differential between the interior region of the vacuum chamber and the cavity, and controlling a temperature of at least a portion of the support such that heat transfer via the gas in the cavity adjusts the temperature of the substrate.

According to a further embodiment, a method of adjusting a temperature of a substrate includes providing the substrate disposed on a support within a vacuum chamber, wherein the support defines a recessed section below the substrate to form a cavity between the support and a bottom surface of the substrate, evacuating an interior region of the vacuum chamber to a high vacuum pressure, preferably at least about 1.0×10⁻⁵ Torr, injecting a gas below the substrate within the cavity while maintaining a pressure differential between the interior region of the vacuum chamber and the cavity by limiting flow out of the cavity due to a fence formed on the support and surrounding the cavity, wherein the bottom surface of the substrate and a top surface of the fence are separated from one another by a gap such that the gap and a width of the fence act to limit the flow out of the cavity, and controlling a temperature of at least a portion of the support such that heat transfer via the gas in the cavity adjusts the temperature of the substrate.

According to still another embodiment, a vacuum chamber assembly for adjusting a temperature of a substrate includes a thermally controlled support within a vacuum chamber. The support defines a recessed section disposed below the substrate to form a cavity between the support and a bottom surface of the substrate, a fence surrounding the recessed section and protruding from the recessed section toward the substrate, and at least three contacts spaced from one another and configured to hold the substrate on the support with a bottom surface of the substrate and a top surface of the fence separated from one another by a predefined gap such that the gap and a width of the fence act to substantially prevent gas flow out of the cavity. A gas inlet into the vacuum chamber assembly is in isolated fluid communication with an injection aperture disposed in the recessed section of the support.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top view of a thermal conditioning plate, according to one embodiment of the invention, with a substrate that is shown transparent disposed thereon.

FIG. 2 is an isometric view of another embodiment of a thermal conditioning plate without the substrate.

FIG. 3 is a cross sectional view of the thermal conditioning plate shown in FIG. 1 taken across line 3-3.

FIG. 4 is an enlarged cross sectional view of an area 4 in FIG. 3.

FIG. 5 is a cross sectional view of the thermal conditioning plate inside a high pressure vacuum chamber and in a lifter down position.

FIG. 6 is a cross sectional view of the thermal conditioning plate in a lifter up position to raise the substrate from the thermal conditioning plate.

### DETAILED DESCRIPTION

The invention provides apparatus and methods to inject rarified gas underneath a substrate to transfer heat between the underside of the substrate and a stage plate just below it, without raising the vacuum pressure within a vacuum chamber beyond acceptable levels and without forming a contact seal between the substrate underside and the stage plate. The stage plate can be thermally controlled. By limiting flow of the gas injected underneath the substrate into an interior region of the vacuum chamber, a pressure differential exists between under the substrate and the interior region of the vacuum chamber. The relatively higher pressure between the stage that is thermally controlled and the substrate enables heat transfer via the gas in order to adjust the temperature of the substrate.

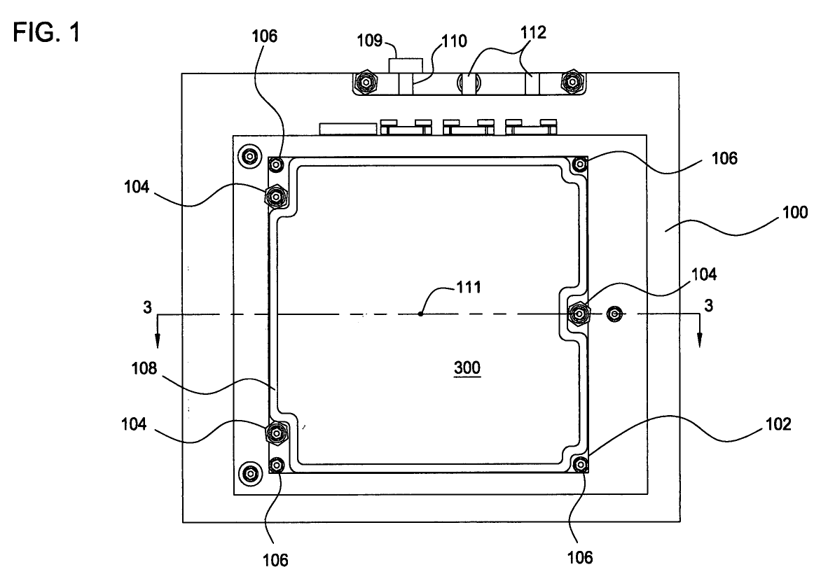

FIG. 1 shows a top view of a thermal conditioning plate 100 or support with a substrate 102 that is illustrated transparent disposed thereon. The plate 100 includes lift pins 104 and rest pins 106 for contacting and supporting the substrate 102 over a cavity area 300 of the plate 100 defined by a fence 108. Further, the plate 100 couples to a gas inlet 110 in fluid communication with an injection aperture 111 disposed within a central region of the cavity area 300 of the plate 100 as better shown in FIG. 3.

The plate 100 can couple to fluid supply and return lines 112 when the temperature of the plate 100 is controlled by a circulating fluid supplied thereto. For example, the plate 100 can incorporate internal water channels (not shown) such that water passing through the water channels adjusts the temperature of the plate proportionately with the temperature of the water as controlled via a feedback resistive thermal device (not shown) coupled to the plate 100. The temperature of the plate 100 affects the temperature of the substrate 102 due to heat transfer via the gas in the cavity area 300.

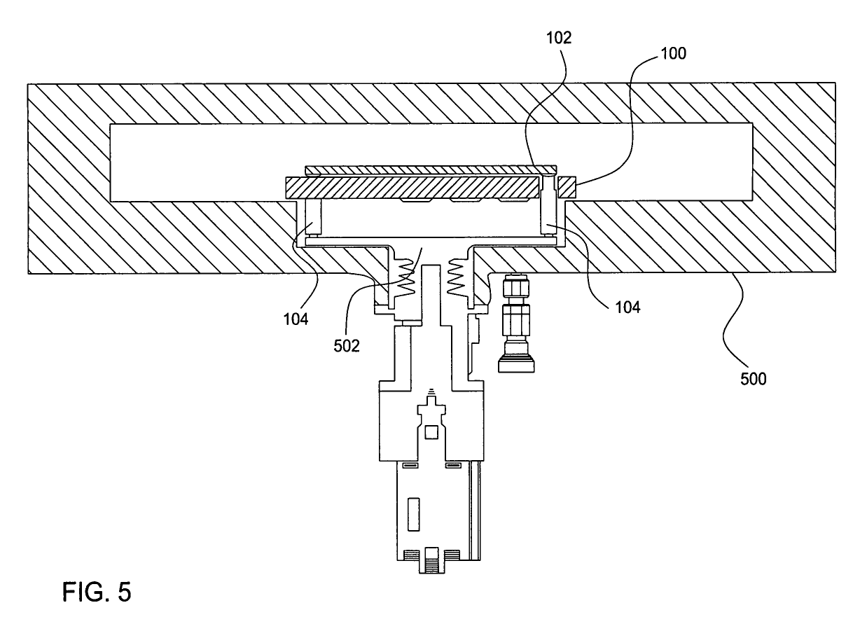

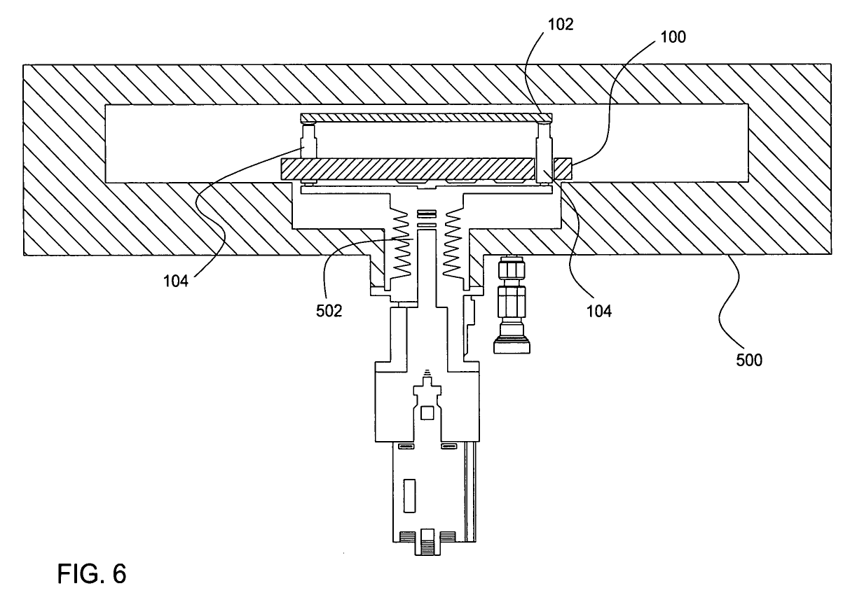

The lift pins 104 pass vertically through the plate 100 and are movable vertically to enable raising and lowering of the substrate 102 (see, FIGS. 5 and 6) with respect to a top surface of the fence 108. As a result, the lift pins 104 facilitate interfacing of any robotic or other substrate transport device with the plate 100. When the lift pins 104 are fully retracted, the substrate sets on the rest pins 106 that are immobile. The rest pins 106 are precisely fixed to keep the underside of the substrate a predefined distance from the top surface of the fence 108.

For some embodiments, the lift and rest pins 104, 106 are disposed outside the perimeter of the fence 108. Further, the plate 100 provides four of the rest pins 106 disposed at each corner of the substrate 102 and three of the lift pins 104. However, any number of the pins 104, 106 capable of stably supporting the substrate 102 while providing point contacts with small actual contact area with the substrate 102 can be used.

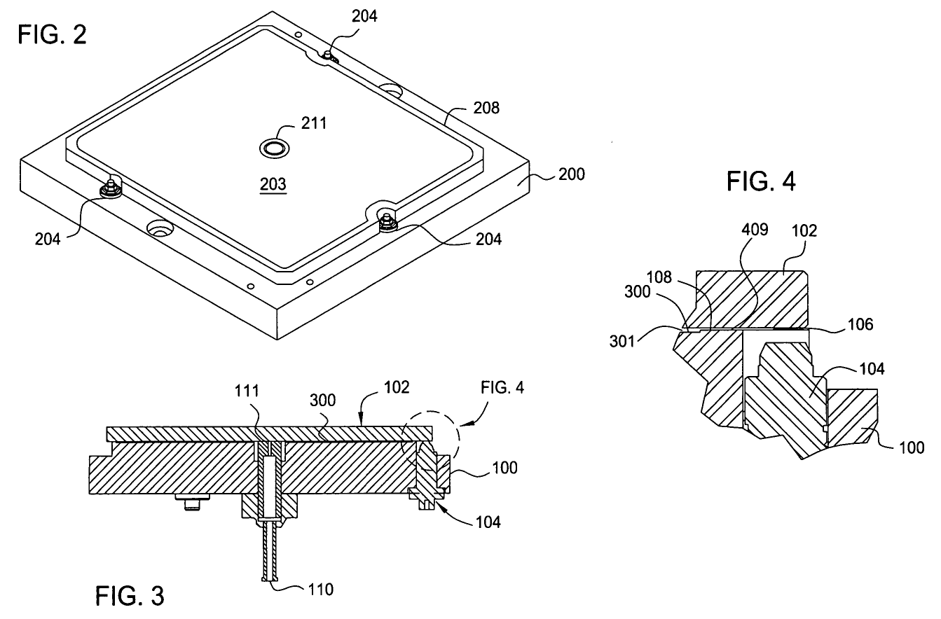

FIG. 2 illustrates another embodiment of a thermal conditioning plate 200 without a substrate disposed on the plate 200. The plate 200 includes lift pins 204 and a fence 208 surrounding an injection aperture 211 that supplies gas to a cavity area 203 provided due to the fence 208. In this embodiment, the lift pins 204 mount to the plate 200 so that the lift pins 204 in a fully retracted position and without the use of optional rest pins support the substrate while leaving a predefined gap between the underside of the substrate and the top surface of the fence 208 with micron accuracy.

FIGS. 3 and 4 show the thermal conditioning plate 100 in cross section. Specifically, the cross section is taken across line 3-3 in FIG. 1 with FIG. 4 illustrating an enlarged cross sectional view of an area 4 in FIG. 3. The fence 108 defines a raised protrusion or lip extending from the top surface of the plate 100 proximate to a perimeter of the substrate 102 to provide the cavity area 300 bounded by the fence 108. The cavity area 300 is recessed relative to the top surface of the fence 108. For some embodiments, the cavity area 300 is machined into the top surface of the plate 100 to create the fence 108 around the outside periphery of the cavity area 300.

As illustrated in FIG. 4, the underside of the substrate 102 sets on the rest pins 106 such that the substrate 102 is disposed above the top surface of the fence 108 leaving the predefined gap 409 between the underside of the substrate 102 and the top surface of the fence 108. The gap 409 limits flow of gas from inside the cavity area 300 to outside of the cavity area 300 due to the small distance of the gap 409. Consequently, the gap 409 acts as a virtual seal keeping relatively high pressure gas (e.g., from about 0.05 to about 0.5 Torr) underneath a majority of the substrate 102 while maintaining a high vacuum pressure level (e.g., preferably between about 1.0×10⁻⁵ and about 1.0×10⁻⁸ Torr) in a vacuum chamber (shown in FIGS. 5 and 6) that the plate 100 and the substrate 102 are disposed.

The width from inside to outside of the fence 108 and the distance of the gap 409 are selected based on the gas flow that is injected into the cavity area 300 via the injection aperture 111, a chosen pressure inside the cavity area 300, pumping speed of a vacuum chamber pump and a desired pressure in the vacuum chamber. For some embodiments, the width of the fence is from about 0.5 to about 10.0 millimeters. Additionally, the distance of the gap 409 is from about 4.0 to 40.0 microns for some embodiments.

The depth 301 of the cavity area 300 relative to the underside of the substrate 102 is selected based on the gas pressure desired underneath the substrate 102. Further, the depth 301 is equal to or slightly more than the mean free path of the gas at the desired pressure in order to provide the maximum thermal conductivity. The mean free path of molecules is defined as the average distance where there is equal probability of a collision with the nearest body as with another gas molecule. Accordingly, the mean free path is a function of molecular diameter of the gas, the depth 301 of the cavity area 300 and the pressure of the gas. Additionally, the depth 301 must be sufficient to prevent the gas flow from the central region of the cavity area 300 where the injection aperture 111 is located to the fence 108 from creating a large pressure gradient. For some embodiments, the depth 301 can range from about 50.0 microns to about 1.0 millimeter. The main requirement for the pressure under the substrate 102 is to not create an upward force large enough to overcome the force of gravity holding the substrate 102 on the rest pins 106.

FIG. 5 shows the thermal conditioning plate 100 inside a high pressure vacuum chamber 500 and in a lifter down position. Each of the lift pins 104 passes through the plate 100 and couples to an actuator and plate assembly 502 such that the lift pins 104 move relative to the plate 100 while moving with the actuator and plate assembly 502. In operation, the lift pins 104 move up and down through the plate 100 in response to actuation of the actuator and plate assembly 502. The lifter down position locates the substrate 102 above the fence 108 to establish the gap 409 that enables creating the pressure differential between an interior region of the chamber 500 where the plate and substrate 100, 102 are disposed and a region between the plate 100 and the substrate 102 provided by the cavity area 300.

FIG. 6 illustrates the thermal conditioning plate 100 in a lifter up position to raise the substrate 102 from the thermal conditioning plate 100. In operation, the actuator and plate assembly 502 moves the lift pins 104 up in order to elevate the substrate 102 above the plate 100. The lifter up position facilitates handling of the substrate 102 with a robotic or other substrate transport device (not shown) since the substrate 102 is spaced from the plate 100.

Any precision gas flow limiting device 109 (e.g., a precision needle valve or mass flow controller) on the gas inlet 110 can be disposed outside the vacuum chamber 500. By slowly raising the flow rate through the gas inlet 110 via the flow limiting device 109 from zero, the pressure in the vacuum chamber 500 rises accordingly from the default static base pressure of the chamber. By this operation, any vacuum pressure gauge already in place on the vacuum chamber 500 can be used as a feedback device for the flow limiting device 109. Once the pressure in the chamber 500 reaches a predetermined level based on the dimensions of the gap 409 and the capacity of a vacuum chamber pumping system, the necessary flow rate to attain the desired pressure under the substrate 102 is reached.

While the foregoing is directed to embodiments of the present invention, other and further embodiments of the invention may be devised without departing from the basic scope thereof, and the scope thereof is determined by the claims that follow.

What is claimed is:

1. A method of adjusting a temperature of a substrate, comprising:
providing the substrate disposed on a support within a vacuum chamber;
evacuating an interior region of the vacuum chamber;
injecting a gas below the substrate within a cavity defined by the support and a bottom surface of the substrate while maintaining a pressure differential between the interior region of the vacuum chamber and the cavity; and
controlling a temperature of at least a portion of the support such that heat transfer via the gas in the cavity adjusts the temperature of the substrate.

2. The method of claim 1, wherein maintaining the pressure differential comprises sustaining pressure in the interior region at a high vacuum pressure.

3. The method of claim 1, wherein maintaining the pressure differential comprises sustaining pressure in the interior region at less than about 1.0×10⁻⁵ Torr and in the cavity at about 0.05 to about 0.5 Torr.

4. The method of claim 1, wherein maintaining the pressure differential is enabled by a predefined gap between the support and the substrate adjacent to a perimeter of the substrate.

5. The method of claim 1, wherein controlling the temperature of at least the portion of the support comprises circulating temperature controlled fluid through channels within the support.

6. The method of claim 1, further comprising monitoring pressure in the vacuum chamber while increasing flow rate of the gas being injected until the pressure in the vacuum chamber reaches a predetermined level above a default static base pressure.

7. A method of adjusting a temperature of a substrate, comprising:
providing the substrate disposed on a support within a vacuum chamber, wherein the support defines a recessed section below the substrate to form a cavity between the support and a bottom surface of the substrate;
evacuating an interior region of the vacuum chamber to at least about 1.0×10⁻⁵ Torr;
injecting a gas below the substrate within the cavity while maintaining a pressure differential between the interior region of the vacuum chamber and the cavity by limiting flow out of the cavity due to a fence formed on the support and surrounding the cavity, wherein the bottom surface of the substrate and a top surface of the fence are separated from one another by a gap such that the gap and a width of the fence act to limit the flow out of the cavity; and
controlling a temperature of at least a portion of the support such that heat transfer via the gas in the cavity adjusts the temperature of the substrate.

8. The method of claim 7, wherein limiting the flow out of the cavity is provided by the width of the fence being from about 0.5 to about 10.0 millimeters.

9. The method of claim 7, wherein limiting the flow out of the cavity is provided by the gap having a distance of between about 4.0 and 40.0 microns.

10. The method of claim 7, wherein limiting the flow out of the cavity is provided by the width of the fence being from about 0.5 to about 10.0 millimeters and the gap having a distance of between about 4.0 and 40.0 microns.

11. The method of claim 7, further comprising adjusting a gas flow limiting device to increase flow rate of the gas being injected until pressure in the vacuum chamber reaches a predetermined level above a default static base pressure.

12. The method of claim 7, wherein heat transfer via the gas in the cavity is enabled by a depth of the cavity between the support and the bottom surface of the substrate being between about 50.0 microns to about 1.0 millimeter.

13. A vacuum chamber assembly for adjusting a temperature of a substrate, comprising:
a thermally controlled support within a vacuum chamber, wherein the support defines:
a recessed section disposed below the substrate to form a cavity between the support and a bottom surface of the substrate;
a fence surrounding the recessed section and protruding from the recessed section toward the substrate; and
at least three contacts spaced from one another and configured to hold the substrate on the support with a bottom surface of the substrate and a top surface of the fence separated from one another by a predefined gap such that the gap and a width of the fence act to substantially prevent gas flow out of the cavity; and
a gas inlet into the vacuum chamber assembly in isolated fluid communication with an injection aperture disposed in the recessed section.

14. The vacuum chamber assembly of claim 13, wherein the at least three contacts are fixed to hold the substrate on the support with the predefined gap that has a distance of between about 4.0 and 40.0 microns.

15. The vacuum chamber assembly of claim 13, wherein the width of the fence is from about 0.5 to about 10.0 millimeters.

16. The vacuum chamber assembly of claim 13, wherein the width of the fence is from about 0.5 to about 10.0 millimeters and the at least three contacts are fixed to hold the substrate on the support with the predefined gap that has a distance of between about 4.0 and 40.0 microns.

17. The vacuum chamber assembly of claim 13, wherein a depth of the cavity between the support and the bottom surface of the substrate is between about 50.0 microns to about 1.0 millimeter.

18. The vacuum chamber assembly of claim 13, further comprising an adjustable gas flow limiting device disposed on the gas inlet.

19. The vacuum chamber assembly of claim 13, further comprising fluid supply and return lines coupled to the support for circulating a temperature controlled fluid through the support.

20. The vacuum chamber assembly of claim 13, further comprising lift pins separate from the at least three contacts, wherein the lift pins are movable relative to the support and coupled to an actuation mechanism for moving the lift pins to raise and lower the substrate.
